(19) United States
(12) Patent Application Publication
(10) Pub. No.: US 2024/0222571 A1
(43) Pub. Date: Jul. 4, 2024

(54) NANOPARTICLE THIN FILMS, MANUFACTURING METHODS THEREOF, AND DISPLAY PANELS

(71) Applicant: SHENZHEN CHINA STAR OPTOELECTRONICS SEMICONDUCTOR DISPLAY TECHNOLOGY CO., LTD., Shenzhen (CN)

(72) Inventor: Jinyang ZHAO, Shenzhen (CN)

(21) Appl. No.: 18/232,572

(22) Filed: Aug. 10, 2023

(30) Foreign Application Priority Data
Dec. 26, 2022 (CN) 2202211678234.2

(51) Int. Cl. H01L 33/50; C09K 11/02

(52) U.S. Cl. CPC H01L 33/502; C09K 11/02; B82Y 20/00

(57) ABSTRACT

A nanoparticle thin film and a manufacturing method thereof, and the display panel are provided. The nanoparticle thin film includes a hyperdispersant and a nanoparticle polymer. A polymerized monomer of the nanoparticle polymer includes a first nanoparticle having a first ligand, a second nanoparticle having a second ligand, and a crosslinking agent having a molecular structure including at least two azide groups, one of the two azide groups polymerizes with the first ligand, and another one of two azide groups polymerizes with the second ligand.

### CROSS-REFERENCE TO RELATED APPLICATION

This application claims priority to and the benefit of Chinese Patent Application No. 202211678234.2, filed on Dec. 26, 2022, the disclosure of which is incorporated herein by reference in its entirety.

### TECHNICAL FIELD

The present disclosure relates to display technologies, and in particular to nanoparticle thin films, manufacturing methods of the nanoparticle thin films, and display panels.

### BACKGROUND

Quantum dots (QDs) are a typical class of nanomaterials, which have the characteristics of small size, high energy conversion efficiency, and have important application prospects in the fields of lighting, display technology, solar cells, optical switches, sensing and detection. Moreover, QDs further have the characteristics of high brightness, narrow emission, adjustable luminous color, and good stability. QDs have become the most potential new materials for display technology in recent years.

QD patterning technologies mainly include inkjet printing and photolithography. The heating and ultraviolet curing of the photolithography process, as well as the flushing of the developer, may affect the stability of quantum dots. Ink requirements of the printing process are too high, and there is no mature and stable material system for mass production. The repeatability is poor and the preparation time is long. Methods for processing QD thin films mainly include a scrape coating method, a spin coating method, etc. In order to achieve the required luminous brightness, the thin film prepared by this method is generally thicker. These greatly limit the development and application. At present, QD patterned films are further processed by an electrodeposition method, but the existing QD materials deposited alone can only prepare separate QD films. Due to the self-absorption effect of QDs, the photoluminescence efficiency of QD films is low, which limits its further application, and the stability of the deposited composite system is poor, and it is easy to be removed by post-processing.

In summary, it is indeed necessary to develop a nanoparticle thin film, manufacturing methods of the nanoparticle thin film, and a display panel to overcome the defects of the prior art.

### SUMMARY

The embodiments of the present disclosure provide a nanoparticle thin film, including a hyperdispersant and a nanoparticle polymer. A polymerized monomer of the nanoparticle polymer includes a first nanoparticle, a second nanoparticle and a crosslinking agent.

A first ligand is bound to a surface of the first nanoparticle, a second ligand is bound to a surface of the second nanoparticle, and a molecular structure of the crosslinking agent includes at least two azide groups.

One of the two azide groups polymerizes with the first ligand, and another one of the two azide groups polymerizes with the second ligand.

Correspondingly, the embodiments of the present disclosure further provide a manufacturing method of a nanoparticle thin film, and the manufacturing method includes following steps.

Providing a first nanoparticle and a second nanoparticle, a surface of the first nanoparticle is bound to a first ligand, and a surface of the second nanoparticle is bound to a second ligand.

Dispersing the first nanoparticle and the second nanoparticle into an organic solvent to obtain a mixed solution.

Adding a hyperdispersant and a crosslinking agent in the mixed solution, a molecular structure of the crosslinking agent includes at least two azide groups, one of the two azide groups polymerizes with the first ligand, and another one of the two azide groups polymerizes with the second ligand.

Performing light treatment on the mixed solution to obtain the nanoparticle thin film.

Correspondingly, the embodiments of the present disclosure further provide a display panel, including the nanoparticle thin film as described in any one of the above.

### BRIEF DESCRIPTION OF THE DRAWINGS

To describe the technical solutions of the embodiments of the present disclosure more clearly, the following briefly introduces the accompanying drawings used in the description of the embodiments of the present disclosure. Apparently, the accompanying drawings described below illustrate only some exemplary embodiments of the present disclosure, and persons skilled in the art may derive other drawings from the drawings without making creative efforts.

FIG. 1 is a polymerization schematic diagram of a first nanoparticle, a second nanoparticle and a crosslinking agent molecule provided by some embodiments of the present disclosure.

FIG. 2 is a principle schematic diagram of a crosslinking reaction of the first nanoparticle, the second nanoparticle and the crosslinking agent provided by some embodiments of the present disclosure.

FIG. 3 is a manufacturing method flowchart of a nanoparticle thin film provided by some embodiments of the present disclosure.

FIG. 4A is a first schematic view of the manufacturing method of the nanoparticle thin film provided by some embodiments of the present disclosure.

FIG. 4B is a second schematic view of the manufacturing method of the nanoparticle thin film provided by some embodiments of the present disclosure.

### DETAILED DESCRIPTION

The technical solutions in the embodiments of the present disclosure will be described clearly and completely hereafter with reference to the accompanying drawings. Apparently, the described embodiments are only a part of but not all embodiments of the present disclosure. All other embodiments obtained by persons of ordinary skill in the art based on the embodiments of the present disclosure without creative efforts shall fall within the protection scope of the present disclosure. In addition, it should be understood that the specific embodiments described herein are merely for illustrate and explaining the present disclosure, and not intended to limit the present disclosure. In the present disclosure, unless stated to the contrary, the used orientation words such as “up” and “down” generally refer to up and down in the actual use or working state of the device, specifically the direction of the drawing in the accompany drawings, and “inside” and “outside” are relative to the outline of the device.

In view of the technical problem of poor stability of a nanoparticle thin film prepared by the existing electrodeposition process, a nanoparticle thin film provided by the embodiments of the present disclosure can improve the above technical problem.

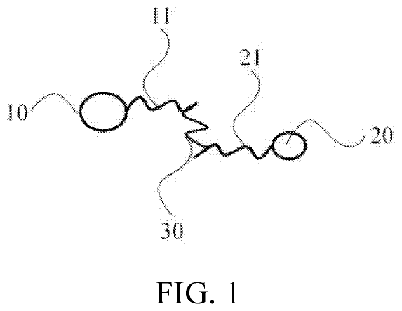

Referring to FIGS. 1 to 4B, the embodiments of the present disclosure provides a nanoparticle thin film, including a hyperdispersant and a nanoparticle polymer. A polymerization monomer of the nanoparticle polymer includes a first nanoparticle 10, a second nanoparticle 20 and a crosslinking agent 30.

A first ligand 11 is bound to a surface of the first nanoparticle 10, a second ligand 21 is bound to a surface of the second nanoparticle 20, and a molecular structure of the crosslinking agent 30 includes at least two azide groups.

One of the two azide groups polymerizes with the first ligand 11, and another one of the two azide groups polymerizes with the second ligand 21.

The crosslinking agent 30 is added to the nanoparticle thin film in the embodiments of the present disclosure, and an azide group of the molecular structure of the crosslinking agent 30 polymerizes with the first ligand 11, another azide group of the molecular structure of the crosslinking agent 30 polymerizes with the second ligand 21, so that a crosslinking reaction occurs between the first ligand 11, the second ligand 21 and the crosslinking agent 30 to obtain the nanoparticle polymer, so that various nanoparticles are aggregated together, thereby improving the stability of the nanoparticle thin film.

The technical solutions of the present disclosure are described in conjunction with specific embodiments.

The embodiments of the present disclosure provide the nanoparticle thin film. The nanoparticle thin film includes the hyperdispersant and the nanoparticle polymer, and the polymerized monomer of the nanoparticle polymer includes the first nanoparticle 10, the second nanoparticle 20 and the crosslinking dose 30.

A first ligand 11 is bound to the surface of the first nanoparticle 10, the second ligand 21 is bound to the surface of the second nanoparticle 20, and the molecular structure of the crosslinking agent includes at least two azide groups.

One of the two azide groups polymerizes with the first ligand 11, and another one of the two azide groups polymerizes with the second ligand 21.

In some embodiments of the present disclosure, the hyperdispersant is a special surfactant, and the molecular structure of the hyperdispersant includes two relative groups in solubility and polarity, one of the two relative groups is a shorter polar group, known as a hydrophilic group, its molecular structure characteristics make it easy to orientate on the surface of the material or the two-phase interface, reduce the interfacial tension, and have a good dispersion effect on the water-based dispersion system. The hyperdispersant is used to make the first nanoparticle 10 and the second nanoparticle 20 can be better dissolved into the organic polar solvent, so that a film thickness of the generated nanoparticle thin film more uniform.

Specifically, the molecular structure of the hyperdispersant is divided into two parts. A part is an anchoring group, such as R₂N, —R₃N⁺, —COOH, —COO⁻, —SO₃H, —SO₂⁻, —PO₄²⁻, polyamine, polyol and polyether, they can be tightly adsorbed on the surface of solid particles through the interaction of ionic bonds, covalent bonds, hydrogen bonds and van der Waals forces to prevent the desorption of the hyperdispersant. The other part is a solvation chain, such as polyester, polyether, polyolefin and polyacrylate. The solvation chain is divided into three types according to polarity: a low polarity polyolefin chain, a medium polar polyester chain or a polyacrylate chain, and a strong polar polyether chain. In the polarity-matched dispersion medium, the solvation chain has good compatibility with the dispersion medium, adopts a relatively extended conformation in the dispersion medium, and forms a protective layer with sufficient thickness on the surface of the solid particle.

In some embodiments of the present disclosure, the first nanoparticle 10 and the second nanoparticle 20 are both nanomaterials, and the nanomaterials refer to a size of their structural units ranging from 1 nanometer to 100 nanometers. Since its size is close to a coherence length of electrons, its properties change greatly due to self-organization brought about by strong coherence. Moreover, its scale is close to the wavelength of light, and it has volume effect, surface effect, quantum size effect and macroscopic quantum tunneling effect, etc., so it has unique properties in terms of melting point, magnetism, optics, thermal conductivity, electrical conductivity, etc., so it has important application value in many fields.

Further, one of the first nanoparticle 10 and the second nanoparticle 20 is a quantum dot nanoparticle. The quantum dot nanoparticle in some embodiments of the present disclosure includes a luminescent core, an inorganic protective shell layer, high-stability composite quantum dots and perovskite quantum dots. Materials of the luminescent core include one or more of ZnCdSe₂, InP, Cd₂SSe, CdSe, Cd₂SeTe and InAs. Materials of the inorganic protective shell layer include one or more of CdS, ZnSe, ZnCdS₂, ZnS, ZnO. Materials of the high-stability composite quantum dot include hydrogel-loaded quantum dots and CdSe—SiO₂. A quantum dot dispersion media includes organic or inorganic reagents having characters of colorless, transparent, low boiling point and volatile.

Further, another one of the first nanoparticle 10 and the second nanoparticle 20 is at least one of inorganic nanoparticles, organic nanoparticles, noble metal nanoparticles, colloidal nanosheet nanoparticles, or colloidal nanorod nanoparticles. The above nanoparticles specifically include at least one of SiO₂, BaSO₄, CaCO₃, ZnSe, CdS, TiO₂, BaTiO₃, ZnS, ZrO₂, Si₃N₄, SnO and ZnO.

In some embodiments of the present disclosure, the first ligand 11 or the second ligand 21 is selected from at least one of a ligand including a sulfhydryl group, a ligand including an amino group, a ligand including a carboxyl group, and a ligand including an organic phosphorus group. The first ligand 11 and the second ligand 21 are used to enable the first nanoparticle 10 and the second nanoparticle 20 to be ionized in a polar solvent, so that the above-mentioned nanoparticles are positively or negatively charged.

Specifically, when the first nanoparticle 10 and the second nanoparticle 20 are negatively charged, the first ligand 11 and the second ligand 21 may include at least one of acid and thiol. When the first nanoparticle 10 and the second nanoparticle 20 are positively charged, the first ligand 11 and the second ligand 21 may include at least one of amine or organic phosphorus.

Further, when the first ligand 11 and the second ligand 21 include at least one of acid and thiol, a hydrogen ion concentration (pH) value of a mixed solution where the first nanoparticle 10 and the second nanoparticle 20 are located can be adjusted to make the first nanoparticle 10 and the second nanoparticle 20 positively charged. When the first ligand 11 and the second ligand 21 includes at least one of amine or organic phosphorus, the pH value of the mixed solution can be adjusted so that the first nanoparticle 10 and the second nanoparticle 20 are negatively charged.

In some embodiments of the present disclosure, the molecular structure of the crosslinking agent 30 includes at least two azide groups. One of the two azide groups polymerizes with the first ligand 11, and another one of the two azide groups polymerizes with the second ligand 21.

In some embodiments of the present disclosure, the crosslinking agent 30 is a photosensitive crosslinking agent, which can undergo a cross-linking reaction with the ligand bound to the nanoparticle under light conditions.

Specifically, as shown in FIG. 1, it is a polymerization schematic diagram of a first nanoparticle 10, a second nanoparticle 20 and a crosslinking agent 30 molecule provided by some embodiments of the present disclosure. Under certain conditions, the first ligand 11 bound to the surface of the first nanoparticle 10 polymerizes with an azide group of the molecule of the crosslinking agent 30. The second ligand 21 bound to the surface of the second nanoparticle 20 polymerizes with another azide group of the molecule of the crosslinking agent 30. Thereby the first nanoparticle 10, the second nanoparticle 20 and the crosslinking agent 30 can polymerize together. Furthermore, the stability of the nanoparticle thin film provided with the first nanoparticle 10 and the second nanoparticle 20 is improved.

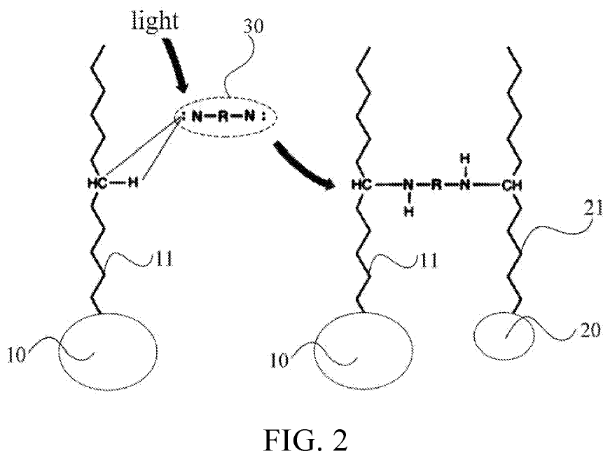

As shown in FIG. 2, it is a principle schematic diagram of a crosslinking reaction of the first nanoparticle 10, the second nanoparticle 20 and the crosslinking agent 30 provided by some embodiments of the present disclosure. The general molecular formula of the crosslinking agent 30 is: N₃—R—N₃.

In the polar aprotic solvent, the azide group of the crosslinking agent 30 is easy to undergo diazo transfer reaction with a methylene group under ultraviolet light conditions.

Specifically, when under the condition of ultraviolet light, an azide group of the crosslinking agent 30 molecule loses two nitrogen atoms, and the remaining nitrogen atom is respectively combined with a hydrogen atom and a carbon atom in the methylene group of the first ligand 11, so that the crosslinking agent 30 molecules polymerizes with the first nanoparticle 10. Similarly, another azide group of the crosslinking agent 30 molecules loses two nitrogen atoms, and the remaining nitrogen atom is combined with a hydrogen atom and a carbon atom in the methylene group of the second ligand 21, so that the crosslinking agent 30 molecules polymerizes with the second ligand 21. The above polymerization reaction aggregates the first nanoparticle 10, the second nanoparticle 20 and the crosslinking agent 30 together, thereby improving the stability of the nanoparticle thin film provided with the first nanoparticle 10 and the second nanoparticle 20.

Further, under ultraviolet light conditions, the two azide groups of the crosslinking agent 30 molecules can undergo polymerization reactions with different first ligands 11, so that a plurality of the first nanometers particles 10 are aggregated. The two azide groups of the crosslinking agent 30 molecules can also undergo polymerization reactions with the second ligands 21, so that a plurality of the second nanoparticle 20 are aggregated. The above reaction can also improve the stability of the nanoparticle thin film.

In some embodiments of the present disclosure, a mass ratio of the first nanoparticle 10 to the second nanoparticle 20 ranges between 0.1 and 10, and a particle diameter of the second nanoparticle 20 is the same as that of the second nanoparticle 20. In the condition that the mass ratio of the first nanoparticle 10 to the second nanoparticle 20 is 1, and the particle diameter of the second nanoparticle 20 is the same as that of the first nanoparticle 10, the stability of the prepared nanoparticle thin film is the best.

In some embodiments of the present disclosure, a mass percentage of the hyperdispersant to a mixture formed by the first nanoparticle and the second nanoparticle ranges from 5% to 50%. When the mass percentage of the hyperdispersant is less than 5%, it is difficult to dissolve the first nanoparticle 10 and the second nanoparticle 20 into the organic polar solvent. When the mass percentage of the hyperdispersant is greater than 50%, it may affect the chemical properties of the generated nanoparticle thin film.

In some embodiments of the present disclosure, the mass percentage of the crosslinking agent 30 to the mixture formed by the first nanoparticle 10 and the second nanoparticle 20 ranges from 5% to 20%. When the mass percentage of the crosslinking agent 30 is less than 5%, it is difficult to effectively improve the stability of the nanoparticle thin film. When the mass percentage of the crosslinking agent 30 is greater than 20%, the excessive crosslinking agent 30 may affect the application of the subsequently prepared nanoparticle thin film.

In some embodiments of the present disclosure, the electrical property of the second nanoparticle 20 is the same as the electrical property of the first nanoparticle 10. The arrangement is for the convenience of subsequent preparation of the nanoparticle thin film by a capacitive deposition process, so that the first nanoparticle 10 and the second nanoparticle 20 are capable of being simultaneously deposited on the same target electrode, so as to facilitate the preparation of the nanoparticle thin film.

In the embodiments of the present disclosure, the crosslinking agent 30 is selected from at least one of polyoxyethylene bis(azide), poly(ethylene glycol) bis(azide) (N₃-PEG-N₃), 1,11-diazido-3,6,9-trioxaundecane, and azide polyethylene glycol amine (N₃-PEG-NH₂). The molecular formula of polyoxyethylene bis(azide) is as follows:

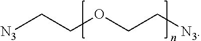

The nanoparticle thin film provided by the embodiment of the present disclosure has a lower refractive index compared to the existing nanoparticle thin film mixed with the first nanoparticle 10 and the second nanoparticle 20. This is due to the addition of a crosslinking agent 30 with a low refractive index to the nanoparticle thin film provided by the embodiments of the present disclosure, which increases the organic component of the nanoparticle thin film, improves the smoothness degree of the surface of the thin film and reduce the refractive index of the thin film.

The refractive index of the existing nanoparticle thin film mixed with the first nanoparticle 10 and the second nanoparticle 20 ranges between 1.8 and 2.0. The refractive index of the nanoparticle thin film provided by the embodiments of the present disclosure ranges between 1.5 to 1.6.

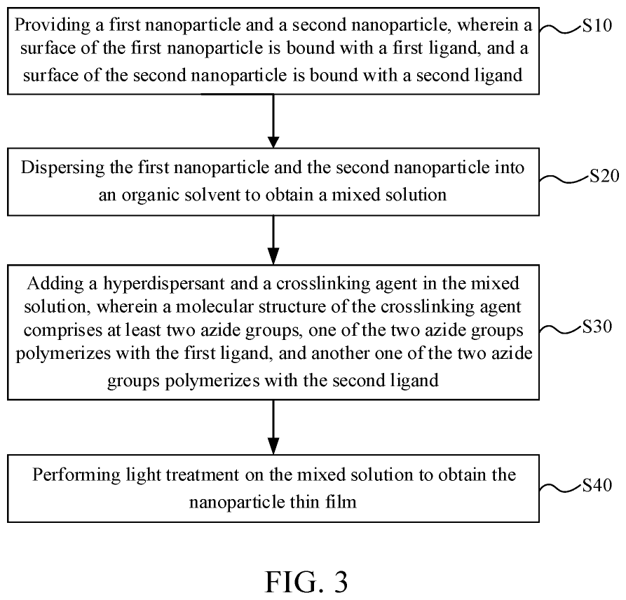

Correspondingly, as shown in FIG. 3, the embodiment of the present disclosure further provides a manufacturing method of the nanoparticle thin film including steps S10, S20, S30, S40, and S50.

At step S10, providing a first nanoparticle 10 and a second nanoparticle 20, a surface of the first nanoparticle 10 is bound to a first ligand 11, and a surface of the second nanoparticle 20 is bound to a second ligand 21.

Specifically, step S10 further includes following steps.

A first nanoparticle 10 and a second nanoparticle 20 are provided, a surface of the first nanoparticle 10 is bound to a first ligand 11, and a surface of the second nanoparticle 20 is bound to a second ligand 21.

The first nanoparticle 10 is a quantum dot nanoparticle. The second nanoparticle 20 is a silica nanoparticle. A particle diameter of the first nanoparticle 10 ranges from 10 nm to 15 nm. A particle diameter of the second nanoparticle 20 ranges from 15 to 30 nm. The first ligand 11 is selected from a mercapto-polyethylene glycol-carboxyl (SH-PEG-COOH) ligand, and the second ligand 21 is selected from a silane polyethylene glycol carboxyl (Silane-PEG-COOH) ligand, so that the first nanoparticle 10 and the second nanoparticle 20 are two kinds of nanoparticles whose end groups are carboxyl groups, and both the first nanoparticle 10 and the second nanoparticle 20 are negatively charged.

At step S20, dispersing the first nanoparticle 10 and the second nanoparticle 20 into an organic solvent to obtain a mixed solution.

Specifically, step S20 further includes following steps.

The first nanoparticle 10 and the second nanoparticle 20 are dispersed in an organic polar solution according to a specific ratio (for example, 1 to 1), and the organic polar solution is selected from a propylene glycol methyl ether acetate (PGMEA) solution.

At step S30, adding a hyperdispersant and a crosslinking agent 30 in the mixed solution, the molecular structure of the crosslinking agent 30 includes at least two azide groups, one of the two azide groups is used for polymerization with the first ligand 11, and another one of the two azide groups is used for polymerization with the second ligand 21.

Specifically, step S30 further includes following step.

Firstly, adding the hyperdispersant and the crosslinking agent 30 in the mixed solution, the molecular structure of the crosslinking agent 30 includes at least two azide groups, one of the two azide groups is used for polymerization with the first ligand 11, and and another one of the two azide groups is used for polymerization with the second ligand 21. A mass percentage of the hyperdispersant to a mixture formed by the first nanoparticle 10 and the second nanoparticle 20 ranges from 5% to 50%, and a mass percentage of the crosslinking agent 30 to a mixture formed by the first nanoparticle 10 and the second nanoparticle 20 ranges from 5% to 20%. The crosslinking agent 30 is preferably polyoxyethylene bis(azide).

Afterwards, the mixed solution is stirred and ultrasonically treated so that the above-mentioned materials can be mixed evenly.

At step S40, performing light treatment on the mixed solution to obtain the nanoparticle thin film.

Specifically, step S40 further includes following steps.

Firstly, a substrate 40 is provided, and the substrate 40 has a patterned electrode structure, that is, the substrate 40 includes a first electrode 41 and a second electrode 42 opposite in polarity to the first electrode 41.

The material of the substrate 40 may include glass, plexiglass, hard insulating film material, soft insulating film material and the like. The materials of the first electrode 41 and the second electrode 42 may be indium tin oxide (ITO), graphene, metal, and transition metal chalcogenides (MoS₂, MoSe₂, WS₂, or WSe₂) and the like.

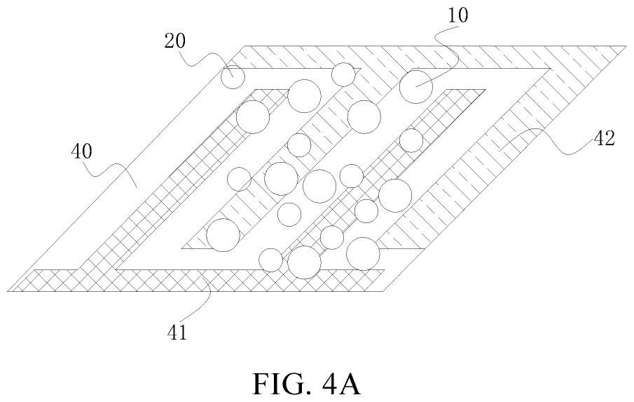

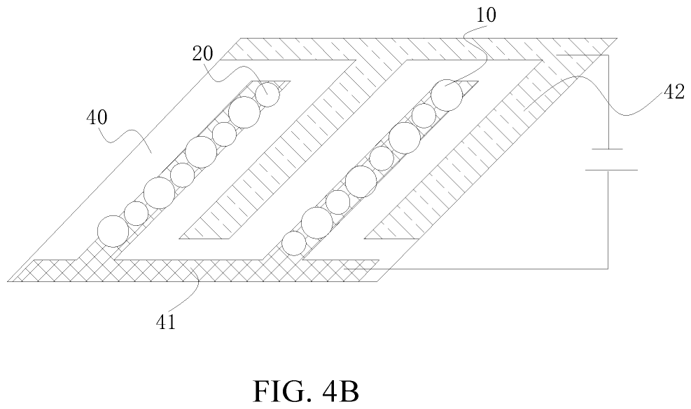

Afterwards, the mixed solution is scraped or drip-coated onto the substrate 40, as shown in FIG. 4A.

Afterwards, a positive voltage is applied to the first electrode 41, a negative voltage is applied to the second electrode 42, and a vertical or horizontal electric field is formed between the first electrode 41 and the second electrode 42. An intensity of the electric field ranges between 0 V/μm and 20 V/μm, and a voltage between the first electrode 41 and the second electrode 42 ranges between 0 V and 1000 V.

The first nanoparticle 10 and the second nanoparticle 20 with the same electrical property move together to the electrode with the opposite electrical property under the action of an electric field. Since both the first nanoparticle 10 and the second nanoparticle 20 are negatively charged, the first nanoparticle 10 and the second nanoparticle 20 jointly move onto the first the electrode 41 under the action of the electric field, as shown in FIG. 4B.

At step S50, performing light treatment on the mixed solution to obtain the nanoparticle thin film.

Specifically, step S50 further includes following steps.

The mixed solution coated on the substrate 40 is subjected to ultraviolet light treatment (ultraviolet light wavelength is 254 nm), the ultraviolet light exposure is greater than 10 mJ/cm², preferably 10-200 mJ/cm². Such setting can make the crosslinking agent 30 in the mixed solution is fully aggregated with the first nanoparticle 10 and the second nanoparticle 20, so that the first nanoparticle 10, the second nanoparticle 20 and the crosslinking agent 30 are stably deposited on the first electrode 41 and will not be washed away by subsequent solvents. Therefore, the problem of unstable electrophoretic deposition of various nanoparticle systems can be solved. The crosslinking agent 30 can not only gather the adjacent first ligand 11 connected to the surface of the first nanoparticle 10 and the second ligand 21 connected to the surface of the second nanoparticle 20 together, but also make two adjacent first ligands 11 aggregate or two adjacent second ligands 21 aggregate, so that stable deposition of various nanomaterials can also be achieved.

In some embodiments of the present disclosure, in order to realize the aggregation of the first nanoparticle 10 and the second nanoparticle 20, the first nanoparticle 10 and the second nanoparticle 20 are required to disperse uniformly in the system, and deposited uniformly on the target electrode, which requires that the electrodeposition speed of the two is similar.

In some embodiments of the present disclosure, the organic solvent used for dissolving the first nanoparticle 10 and the second nanoparticle 20 has characters of colorless, transparent, and low boiling point/volatile, which may be selected form other polar solvents besides for 2-acetoxy-1-methoxypropane (PGMEA), such as ethanol, N,N-dimethylformamide (DMF), dimethyl sulfoxide (DMSO), ethyl acetate and many other polar solvents. The first ligand 11 and the second ligand 21 may be selected from various types of ligands, such as ligands whose end groups are PEG-NH₂, ligands with sulfhydryl, amino, or carboxyl groups. The types of ligands are capable of ionizing in the polar solvents, to make the nanoparticles positively or negatively charged. Based on this, patterning processing of electrodeposition can be realized.

The embodiments of the present disclosure provide a composite system of various nanoparticles for electrodeposition processing, which uses an electric field to drive various nanoparticles to move together and deposit on the electrode. By adding the crosslinking agent 30 to the composite system, a cross-linking reaction between various nanoparticle ligands can be realized by means of light, so that various nanoparticles can be aggregated together and deposited on the electrode stably without being washed away by subsequent solution. The addition of the crosslinking agent 30 with low refractive index improves the organic components of the deposited film, improves the flatness of the surface of the film and reduces the refractive index of the film, thereby improving the light extraction efficiency of the film, thereby improving the light efficiency of the film.

Correspondingly, the embodiments of the present disclosure further provide a display panel, including the nanoparticle thin film described in any one of the above.

When one of the first nanoparticle 10 and the second nanoparticle 20 is a quantum dot nanoparticle, the nanoparticle thin film can be applied to the field of quantum dot display and the field of nanoparticle patterning process, such as a quantum dot color filter (QDCF), a quantum dot light guide plate (QD LGP), a quantum dot light emitting Diode (QLED), or a quantum dot organic light emitting diode (QD-OLED).

When the nanoparticle thin film is applied to the quantum dot light-emitting diode, the nanoparticle thin film is used to convert the blue light emitted by the light-emitting diode into red light or green light.

Specifically, when using the quantum dot film of the prior art to prepare a quantum dot light-emitting diode, its brightness conversion efficiency for red light is 30%, and its brightness conversion efficiency for green light is 70%. When using the nanoparticle thin film provided by the present disclosure to prepare a quantum dot light-emitting diode, and in the case of the first nanoparticle 10 selected from conventional nanoparticles, the second nanoparticle 20 selected from SiO₂ nanoparticles, and the crosslinking agent 30 selected from polyoxyethylene bis(azide), its brightness conversion efficiency for red light is 90%, and its brightness conversion efficiency for green light is 140%.

In summary, the embodiments of the present disclosure provide the nanoparticle thin film and the manufacturing method thereof, and the display panel. the nanoparticle thin film includes the hyperdispersant and the nanoparticle polymer, and the polymerized monomer of the nanoparticle polymer includes the first nanoparticle 10, the second nanoparticle 20 and the crosslinking agent 30. The first ligand is bound to a surface of the first nanoparticle, and the second ligand is bound to a surface of the second nanoparticle. The molecular structure of the crosslinking agent includes at least two azide groups, one of the two azide groups is used to polymerize with the first ligand, and another one of the two azide groups is used to polymerize with the second ligand. By adding the crosslinking agent 30 in the nanoparticle thin film, and an azide group in the molecular structure of the crosslinking agent 30 can polymerize with the first ligand 11, another azide group in the molecular structure of the crosslinking agent 30 can polymerize with the second ligand 21, so that the crosslinking reaction can occur between the first ligand 11, the second ligand 21 and the crosslinking agent 30 to obtain the nanoparticle polymer, so that various nanoparticles aggregate together, thereby improving the stability of the nanoparticle thin film.

The nanoparticle thin film and the manufacturing method thereof, and the display panel provided in the embodiments of the present disclosure are described in detail above. The principle and implementations of the present disclosure are described in this specification by using specific examples. The description about the foregoing embodiments is merely provided to help understand the method and core ideas of the present disclosure. In addition, persons of ordinary skill in the art can make modifications in terms of the specific implementations and application scopes according to the ideas of the present disclosure. Therefore, the content of this specification shall not be construed as a limit to the present disclosure.

What is claimed is:

1. A nanoparticle thin film, comprising a hyperdispersant and a nanoparticle polymer, wherein a polymerized monomer of the nanoparticle polymer comprises a first nanoparticle, a second nanoparticle, and a crosslinking agent;
wherein a first ligand is bound to a surface of the first nanoparticle, a second ligand is bound to a surface of the second nanoparticle, and a molecular structure of the crosslinking agent comprises at least two azide groups; and
one of the two azide groups polymerizes with the first ligand, and another one of the two azide groups polymerizes with the second ligand.

2. The nanoparticle thin film of claim 1, wherein a mass percentage of the hyperdispersant to a mixture formed by the first nanoparticle and the second nanoparticle ranges from 5% to 50%, and a mass percentage of the crosslinking agent to a mixture formed by the first nanoparticle and the second nanoparticle ranges from 5% to 20%.

3. The nanoparticle thin film of claim 1, wherein one of the first nanoparticle and the second nanoparticle is a quantum dot nanoparticle, and another one of the first nanoparticle and the second nanoparticle is at least one of inorganic nanoparticles, organic nanoparticles, noble metal nanoparticles, colloidal nanosheet nanoparticles, or colloidal nanorod nanoparticles.

4. The nanoparticle thin film of claim 3, wherein a mass ratio of the first nanoparticle to the second nanoparticle ranges between 0.1 and 10, and a particle diameter of the second nanoparticle and a particle diameter of the first nanoparticle are same.

5. The nanoparticle thin film of claim 3, wherein an electrical property of the second nanoparticle and an electrical property of the first nanoparticle are same.

6. The nanoparticle thin film of claim 1, wherein the first ligand or the second ligand is selected from at least one of a ligand comprising a sulfhydryl group, a ligand comprising an amino group, a ligand comprising a carboxyl group, and a ligand comprising an organic phosphorus group.

7. The nanoparticle thin film of claim 1, wherein the crosslinking agent is a photosensitive crosslinking agent.

8. The nanoparticle thin film of claim 7, wherein the crosslinking agent is selected from at least one of polyoxyethylene bis(azide), poly(ethylene glycol) bis(azide), 1,11-diazido-3,6,9-trioxaundecane, and azide polyethylene glycol amine (N₃-PEG-NH₂).

9. The nanoparticle thin film of claim 1, wherein a molecular structure of the hyperdispersant comprises an anchor group and a solvation chain, the anchor group comprise at least one of —R₂N, —R₃N⁺, —COO—, —SO₃H, —SO₂⁻, —PO₄²⁻, polyamine, polyol, and polyether, and the solvation chain comprises at least one of polyester, polyether, polyolefin, and polyacrylate.

10. The nanoparticle thin film of claim 1, wherein at least one of the first nanoparticle and the second nanoparticle comprise at least one of SiO₂, BaSO₄, CaCO₃, ZnSe, CdS, TiO₂, BaTiO₃, ZnS, ZrO₂, Si₃N₄, SnO, and ZnO.

11. A manufacturing method of a nanoparticle thin film, wherein the manufacturing method comprises:
providing a first nanoparticle and a second nanoparticle, wherein a surface of the first nanoparticle is bound to a first ligand, and a surface of the second nanoparticle is bound to a second ligand;
dispersing the first nanoparticle and the second nanoparticle into an organic solvent to obtain a mixed solution;
adding a hyperdispersant and a crosslinking agent in the mixed solution, wherein a molecular structure of the crosslinking agent comprises at least two azide groups, one of the two azide groups polymerizes with the first ligand, and another one of the two azide groups polymerizes with the second ligand; and
performing light treatment on the mixed solution to obtain the nanoparticle thin film.

12. The manufacturing method of claim 11, wherein a step of the performing light treatment on the mixed solution to obtain the nanoparticle thin film comprises:
coating the mixed solution on a substrate, the substrate comprising two electrodes with opposite polarities;
applying voltages to the two electrodes, wherein the first nanoparticle and the second nanoparticle are deposited on a surface of one of the two electrodes with an opposite electrical property to the first nanoparticle and the second nanoparticle; and
performing light treatment on the mixed solution to obtain the nanoparticle thin film.

13. A display panel, comprising a nanoparticle thin film, wherein the nanoparticle thin film comprises a hyperdispersant and a nanoparticle polymer, and a polymerized monomer of the nanoparticle polymer comprises a first nanoparticle, a second nanoparticle, and a crosslinking agent;
wherein a first ligand is bound to a surface of the first nanoparticle, a second ligand is bound to a surface of the second nanoparticle, and a molecular structure of the crosslinking agent comprises at least two azide groups; and
one of the two azide groups polymerizes with the first ligand, and another one of the two azide groups polymerizes with the second ligand.

14. The display panel of claim 13, wherein a mass percentage of the hyperdispersant to a mixture formed by the first nanoparticle and the second nanoparticle ranges from 5% to 50%, and a mass percentage of the crosslinking agent to a mixture formed by the first nanoparticle and the second nanoparticle ranges from 5% to 20%.

15. The display panel of claim 13, wherein one of the first nanoparticle and the second nanoparticle is a quantum dot nanoparticle, and another one of the first nanoparticle and the second nanoparticle is at least one of inorganic nanoparticles, organic nanoparticles, noble metal nanoparticles, colloidal nanosheet nanoparticles, or colloidal nanorod nanoparticles.

16. The display panel of claim 15, wherein a mass ratio of the first nanoparticle to the second nanoparticle ranges between 0.1 and 10, and a particle diameter of the second nanoparticle and a particle diameter of the first nanoparticle are same.

17. The display panel of claim 15, wherein an electrical property of the second nanoparticle and an electrical property of the first nanoparticle are same.

18. The display panel of claim 13, wherein the first ligand or the second ligand is selected from at least one of a ligand comprising a sulfhydryl group, a ligand comprising an amino group, a ligand comprising a carboxyl group, and a ligand comprising an organic phosphorus group.

19. The display panel of claim 13, wherein the crosslinking agent is a photosensitive crosslinking agent.

20. The display panel of claim 19, wherein the crosslinking agent is selected from at least one of polyoxyethylene bis(azide), poly(ethylene glycol) bis(azide), 1,11-diazido-3,6,9-trioxaundecane, and azide polyethylene glycol amine (N₃-PEG-NH₂).
